(19) United States
(12) Patent Application Publication
(10) Pub. No.: US 2010/0032737 A1
(43) Pub. Date: Feb. 11, 2010

(54) Nano-magnetic memory device and method of manufacturing the device

(75) Inventors: Kwang Soo Seol, Suwon-si (KR); Jae Young Choi, Suwon-si (KR); Dong Kee Yi, Seoul (KR); Seong Jae Choi, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/604,679

(22) Filed: Nov. 28, 2006

(30) Foreign Application Priority Data
Mar. 30, 2006 (KR) 10-2006-0028988

(51) Int. Cl. H01L 29/82; H01L 21/00

(52) U.S. Cl. 257/295; 438/3; 257/421; 257/E21.001; 977/943; 977/712; 257/E29.323

(57) ABSTRACT

A nano-magnetic memory device capable of writing/reading multi data in the nano-magnetic memory cell by controlling an amount of an induced current which is formed after a magnetic nanodot is perturbed and rearranged according to a word line current flowing from the first electrode through a nanowire of the nano-magnetic memory device to the second electrode. Consequently, a size of the memory device is reduced and a density of the memory device may be improved by providing a simplified nano-magnetic memory device of which a cell size is smaller.

### CROSS-REFERENCE TO RELATED APPLICATION

This application claims the benefit of Korean Patent Application No. 10-2006-0028988, filed on Mar. 30, 2006, in the Korean Intellectual Property Office, the disclosure of which is incorporated herein by reference.

### BACKGROUND OF THE INVENTION

1. Field of the Invention

The present invention relates to a nano-magnetic memory device, and more particularly, to a nano-magnetic memory device capable of writing/reading plurality of data in a nano-magnetic memory cell by controlling an amount of an induced current which is formed after a magnetic nanodot is perturbed and rearranged according to a word line current flowing from a first electrode through a nanowire of the nano-magnetic memory device to a second electrode.

2. Description of Related Art

Currently, most manufacturing providers of semiconductor memory are keen on developing a magnetic random access memory (MRAM) utilizing a ferromagnetic material as one of a next generation memory device.

The MRAM is a type of a memory device capable of writing/reading data by forming a plurality of ferromagnetic thin film layers and sensing a current change according to a magnetization direction of each of the thin films. Normally, the MRAM is composed of various cell types, e.g. a giant magnetoresistance (GMR) type, a magnetic tunnel junction (MTJ) type, and the like. The MRAM accomplishes a memory device by utilizing a GMR effect which caused by a spin has a great effect on an electron delivery and a spin polarization tunneling effect. In this case, the MRAM utilizing the GMR effect is accomplished by using an effect that a resistance difference is greater in the case a spin direction is not identical than in the case the spin direction is identical in two magnetic layers having an antimagnetic layer therebetween. An MRAM utilizing the spin polarization tunneling effect is accomplished by using an effect that a current tunneling more easily occurs in the case a spin direction is identical than when the spin direction is not identical, in two layers having an insulation layer therebetween.

FIG. 1 is a cross-sectional view illustrating an MTJ cell as a multi-layered magnetic thin film structure of a conventional magnetoresistive RAM.

Referring to FIG. 1, the MTJ cell 100 includes an anti-ferromagnetic thin film 101, a fixed layer ferromagnetic thin film 102, a thin insulation layer 103 in which a tunneling current flows, and a free layer ferromagnetic thin film 104. In this case, a magnetization direction of the fixed layer ferromagnetic thin film 102 is fixed in one direction, and the anti-ferromagnetic thin film 101 fixes the magnetization direction of the fixed layer ferromagnetic thin film 102 to not change. In order to not change the magnetization direction of the fixed layer ferromagnetic thin film 102, a SAF (synthetic antiferromagnet) structure may be formed. Conversely, a magnetization direction of the free layer ferromagnetic thin film 104 changes according to an external magnetic field. According to the magnetization direction of the free layer ferromagnetic thin film 104, data, i.e. a “0” or a “1”, may be stored. When a current flows in a vertical direction of the MTJ cell 100, the tunneling current flowing through the thin insulation layer 103 occurs. In this case, when magnetization directions of the fixed layer ferromagnetic thin film 102 and the free layer ferromagnetic thin film 104 are opposite, a small tunneling current begins to flow.

The above described effect is called a tunneling magnetoresistance (TMR) effect. By sensing strength of the tunneling current, the direction of the free layer ferromagnetic thin film 104 is identified and the data is stored in the MTJ cell.

FIG. 2 is a cross-sectional view illustrating a magnetoresistive RAM cell corresponding to a conventional magnetoresistive RAM.

Referring to FIG. 2, a ground wire 207 is formed on a top of a source area 205 of a field effect transistor, and a read word line 201 is formed on a top of a gate. Also, a first conductive layer 208, a contact plug 209, a second conductive layer 210, and another contact plug 211 are sequentially formed on a top of a drain area 206. Also, a connection layer 212 is formed on a top of a write word line 203, and an MTJ cell 100 and a bit line 202 are stacked on a top of the connection layer 212.

The read word line 201 is used to read data. The write word line 203 forms an external magnetic field according to a current supply to store the data according to a change of the magnetization direction of the free layer ferromagnetic thin film 104 in FIG. 1 within the MTJ cell 100. The bit line 202 vertically supplies the MTJ cell 100 with a current to identify the magnetization direction of the free layer ferromagnetic thin film 104 in FIG. 1. The conventional MRAM having the aforementioned structure, when reading, adds a voltage to the read word line 201 the to operate the field effect transistor 204 and identifies an amount of the current which flows in the MTJ cell 100 after supplying the bit line with the current. Also, when writing, the conventional MRAM supplies the write word line 203 and the bit line 202 with the current while maintaining the field-effect transistor 204 in an off state, and subsequently the magnetization direction of the free layer ferromagnetic thin film 104 in FIG. 1 of the MTJ cell 100 changes.

FIG. 3 is a diagram illustrating a conventional MRAM cell array.

Referring to FIG. 3, the conventional MRAM cell has a 1T+1MTJ structure having one switching device transistor T and one MTJ. In particular, the conventional MRAM cell includes a plurality of word lines, i.e. WL1 through WL4, and a plurality of bit lines, i.e. BL1 and BL2, and a cell 301 which is selected by the plurality of word lines and the plurality of bit lines, and includes a sensing amp, i.e. SA1 and SA2. In the conventional MRAM cell having the above described structure, the cell is selected by word lines selection signals WL1 through WL4, and when a predetermined voltage is added to the MTJ through the switching device T, a sensing current which flows in the bit lines BL1 and BL2 becomes different according to a polarity of the MTJ. Accordingly, by amplifying the sensing current by the sensing amp SA1 and SA2, the data may be read.

Since the conventional MRAM includes the ground wire 207, the read word line 201, the write word line 203, and the bit line 202, and four metal wires are allocated to per cell, a wiring structure becomes complicated. Also, in the conventional MRAM having the above described structure, since cell size becomes 8F², which is comparatively larger size, and since an effective size becomes larger, a density of a memory device becomes lower, which is a disadvantageous property for a cell design.

When a size of a memory cell becomes smaller, a problem of a current magnetic field is able to be solved according to the present invention, which is necessary for a magnetization reversal, and contrary to an MRAM using a metal ferromagnetic thin film of a conventional art.

Also, as described above, since one cell has the 1T+1MTJ structure in the conventional MRAM, the cell structure becomes complicated, and one cell has a transistor T and MTJ respectively, so that a manufacturing process of a cell structure becomes complicated.

Also, the conventional MRAM cell has a critical point on improving a density of a memory device because a number of metal wires for each cell increases as in the above described structural problem.

### BRIEF SUMMARY

The present invention provides a nano-magnetic memory device capable of writing/reading plurality of data in the nano-magnetic memory cell by controlling an amount of an induced current which is formed after a magnetic nanodot is perturbed and rearranged according to a word line current flowing from the first electrode through a nanowire of the nano-magnetic memory device to the second electrode, and consequently, a size of the memory device is reduced and a density of the memory device may be improved by providing the simplified nano-magnetic memory device, of which a cell size is smaller.

The present invention also provides a nano-magnetic memory device capable of improving a density of a memory device and planning an effective cell design by reducing an effective size in which a cell of the memory device occupies.

The present invention also provides a nano-magnetic memory manufacturing method capable of mass producing a memory device by solving a problem of a current magnetic field necessary for a magnetization reversal, contrary to an MRAM using a conventional metal ferromagnetic thin film.

The present invention also provides a nano-magnetic memory device capable of making a manufacturing process simple by simplifying a cell structure of a conventional memory device.

The present invention also provides a nano-magnetic memory device capable of improving a density of a memory device by decreasing a number of metal wires for each cell.

The present invention also provides a nano-magnetic memory device including: a first dielectric layer stacked on an insulation substrate; a first electrode and a second electrode formed in both sides of the first dielectric layer; a nanowire connecting the first electrode and the second electrode, and stacked on a top surface of the first dielectric layer; at least one magnetic nanodot formed on a top surface of the nanowire; a second dielectric layer stacked on a top surface of the magnetic nanodot; and a magnetic thin film layer stacked on a top surface of the second dielectric layer, wherein the nano-magnetic memory device writes/reads a plurality of data in the nano-magnetic memory cell by controlling an amount of an induced current which is formed after the magnetic nanodot is perturbed and rearranged according to a word line current flowing from the first electrode through the nanowire to the second electrode.

According to an aspect of the present invention, there is provided a nano-magnetic memory device including: a plurality of nano-magnetic memory cells which an identical first bit line and a first electrode of the plurality of nano-magnetic memory cells are connected, wherein each individual drain of a plurality of metal-Oxide-Silicon (MOS) transistors is respectively connected to a second electrode of the plurality of the nano-magnetic memory cells, each individual source of the plurality of MOS transistors is respectively connected to a second bit line, and an individual gate of the plurality of MOS transistors is respectively connected to a different word line.

According to another aspect of the present invention, there is provided a nano-magnetic memory device including: a plurality of nano-magnetic memory cells connected to an identical bit line, wherein a first electrode of the plurality of nano-magnetic memory cells is connected to the bit line, a second electrode of the plurality of nano-magnetic memory cells connected to a different word line and the word line is connected to a selection transistor.

According to still another aspect of the present invention, there is provided a nano-magnetic memory device manufacturing method including: stacking a first dielectric layer on an insulation substrate; forming a first electrode and a second electrode in both sides of the first dielectric layer; stacking a nanowire on a top surface of the first dielectric layer connecting the first electrode and the second electrode; forming at least one magnetic nanodot on a top surface of the nanowire; stacking a second dielectric layer on a top surface of the magnetic nanodot; and stacking a magnetic thin film layer on a top surface of the second dielectric layer, wherein the nano-magnetic memory device writes/reads a plurality of data in the nano-magnetic memory cell by controlling an amount of an induced current which is formed after the at least one magnetic nanodot is perturbed and rearranged according to a word line current flowing from the first electrode through the nanowire to the second electrode.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a cross-sectional view illustrating an MTJ cell as a multi-layered magnetic thin film structure of a conventional magnetoresistive RAM;

FIG. 2 is a cross-sectional view illustrating a magnetoresistive RAM cell corresponding to a conventional magnetoresistive RAM;

FIG. 3 is a diagram illustrating a conventional MRAM cell array;

FIG. 4 is a cross-sectional view illustrating a cell of a nano-magnetic memory device according to an exemplary embodiment of the present invention;

FIG. 5A is a cross-sectional view cut along a dotted line in FIG. 4 and illustrating a cell structure of the nano-magnetic memory device in FIG. 4;

FIG. 5B, parts I) through XI) illustrates a method of manufacturing a nano-magnetic memory device according to an exemplary embodiment of the present invention;

FIG. 6 is a diagram illustrating operation of a nano-magnetic memory device in a write mode according to an exemplary embodiment of the present invention;

FIG. 7 is a cross-sectional view illustrating a state of the nano-magnetic memory device cell in which different data is respectively recorded on each magnetic thin film by a current flowing in the nanowire of FIG. 6;

FIG. 8 is a diagram illustrating a current pulse signal for reading data in a state of “1” which is supplied to a nano-magnetic memory device cell, and a resultant outputted current pulse signal;

FIG. 9 is a diagram illustrating a current pulse signal for reading data in a state of “0” which is supplied to a nano-magnetic memory device cell, and a resultant outputted current pulse signal;

FIG. 10 is a diagram illustrating operations, when a current pulse for reading in a positive direction is supplied, after the magnetic nanodot is perturbed according to an effect of a magnetic thin film in which data is recorded and a magnetic moment is rearranged in a predetermined relaxation time;

FIG. 11 is a diagram illustrating a highly integrated NOR type memory array in which a cell array of a nano-magnetic memory device is embodied according to an exemplary embodiment of the present invention; and

FIG. 12 is a diagram illustrating a highly integrated cross-point memory array in which a cell array of a nano-magnetic memory device is embodied according to an exemplary embodiment of the present invention.

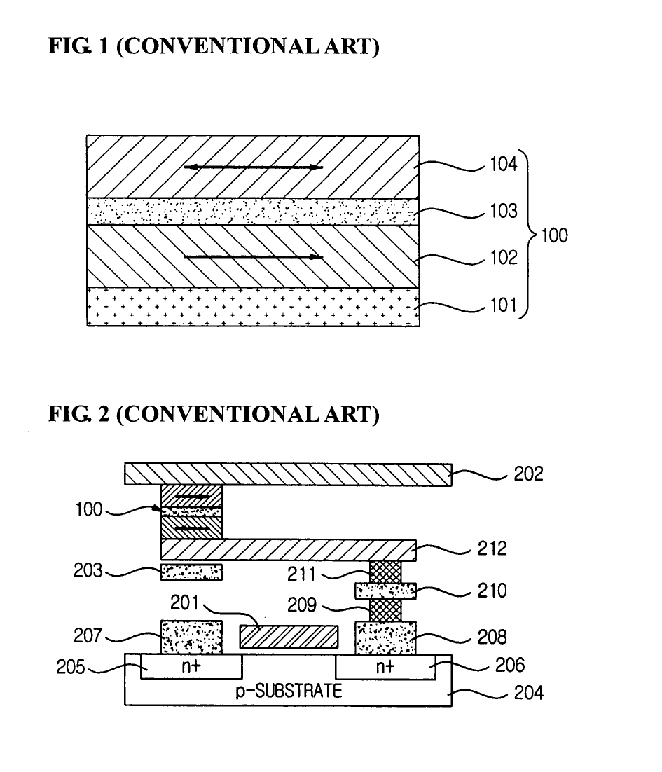

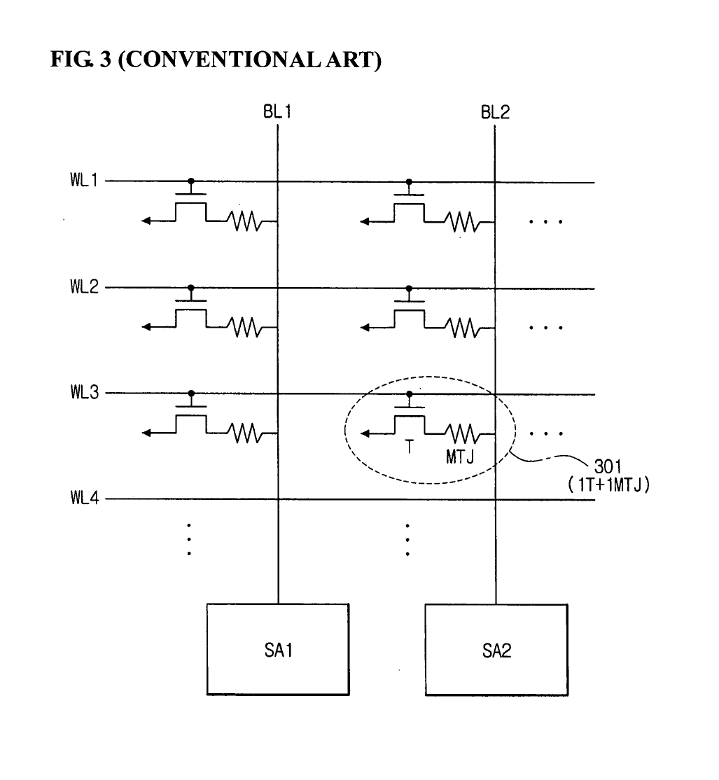

### DETAILED DESCRIPTION OF EXEMPLARY EMBODIMENTS

Reference will now be made in detail to embodiments of the present invention, examples of which are illustrated in the accompanying drawings, wherein like reference numerals refer to the like elements throughout. The embodiments are described below in order to explain the present invention by referring to the figures.

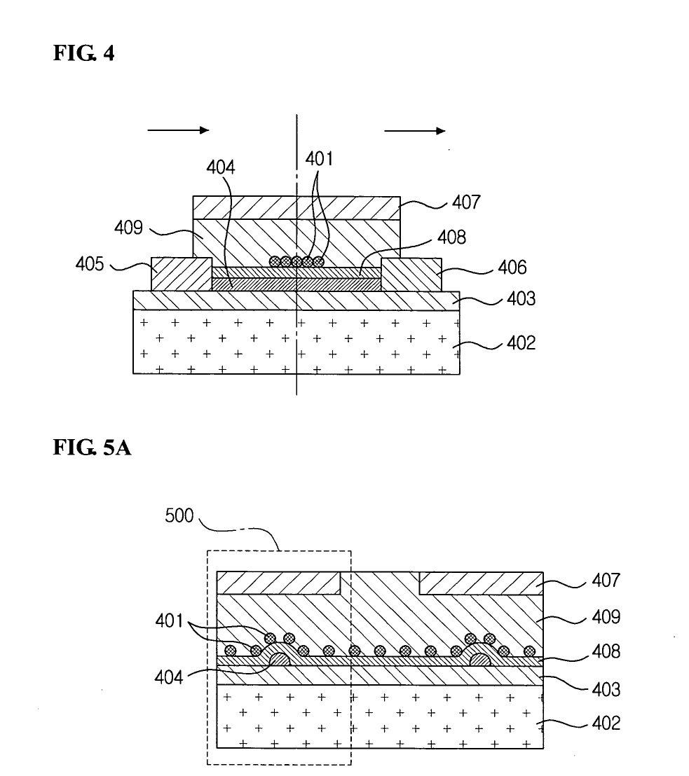

FIG. 4 is a cross-sectional view illustrating a cell of a nano-magnetic memory device according to an exemplary embodiment of the present invention.

Referring to FIG. 4, the cell of a nano-magnetic memory device according the present invention includes a magnetic nanodot 401, an insulation substrate 402, an insulation thin film 403, a nanowire or a nanotube 404 (hereinafter, referred to as ‘nanowire’), a first electrode 405, a second electrode 406, and a magnetic thin film 407.

The insulation thin film 403 is stacked on the insulation substrate 402, and the first electrode 405 and the second electrode 406, which are metal electrodes, are formed on the insulation thin film 403 through a predetermined lithography-process. After forming the metal electrodes, the nanowire 404 is stacked on the insulation thin film 403 through a predetermined process. After stacking another insulation thin film 408 on the nanowire 404, the magnetic nanodot 401 is formed on the other insulation thin film 408. After this, still another insulation thin film 409 is stacked on the magnetic nanodot 401, and the magnetic thin film 407 is stacked on the still another insulation thin film 409, and consequently the cell of the nano-magnetic memory device is completed according the present exemplary embodiment.

A method of manufacturing monodisperse magnetic particles, e.g. cobalt (Co), having a diameter of approximately 5 to 50 nanometers is disclosed in Korean Patent Application No. 99-27259, e.g. the Murray. The method of manufacturing the magnetic Co particles i.e. an average diameter of approximately 8 to 10 nanometers and a standard deviation of a size distribution of approximately 5%, is disclosed in the Murray. Also, a method of manufacturing layers, i.e. one layer or multiple layer, of a magnetic particle having a diameter of up to approximately 50 nanometers, and a regular and a periodical array is disclosed in Korean Patent Application No. 99-0028700.

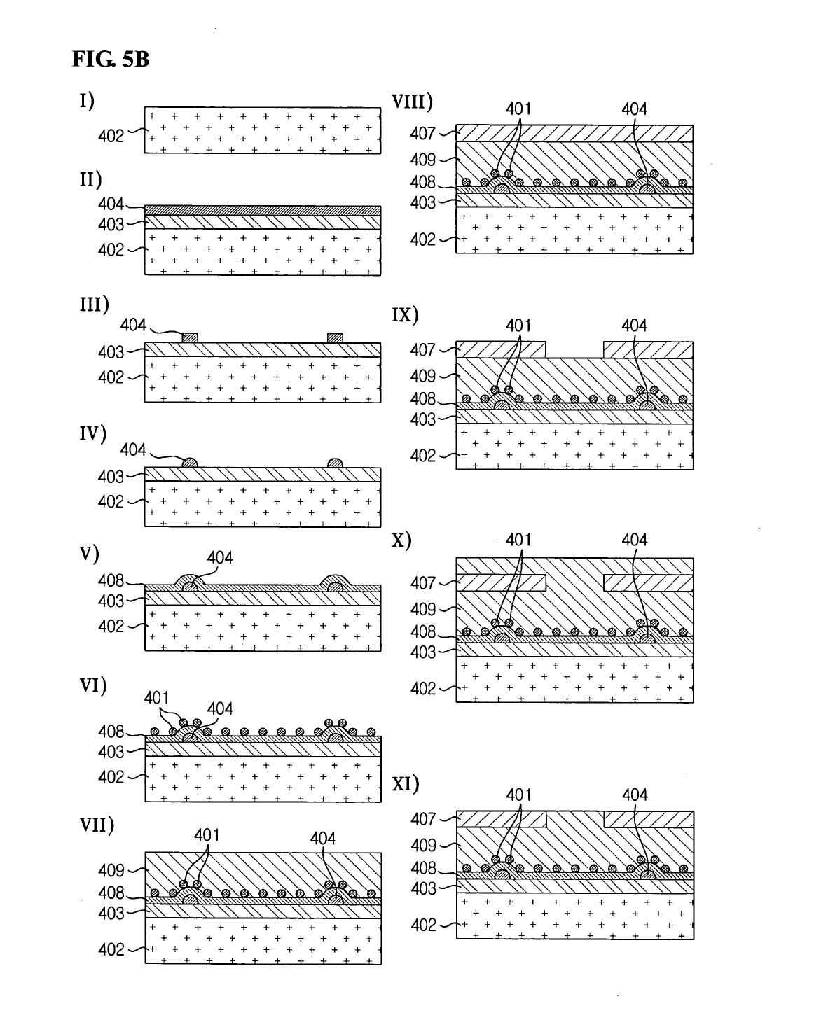

FIG. 5A is a cross-sectional view cut along a dotted line in FIG. 4 and illustrates a cell structure of the nano-magnetic memory device in FIG. 4.

Referring to FIG. 4, FIG. 5A will be described as follows. The insulation thin film 403 is stacked on the insulation substrate 402 along the dotted line in FIG. 4, the nanowire 404 is formed on the insulation thin film 403, the other insulation thin film 408 is stacked on the nanotobe 404, and the magnetic nanodot 401 is formed on the other insulation thin film 408, the still another insulation thin film 403 is sequentially stacked on the magnetic nanodot 401, and the magnetic thin film 407 is stacked thereon. The aforementioned structure forms one bit unit cell 500, and the one bit unit cell 500 may be arranged in a regular array type. A manufacturing method of the nano-magnetic memory device cell will be described in detail with reference to FIG. 5B.

The nanowire 404 may include any one of a metal, a semiconductor and an organic conductive material, which has a diameter of below approximately 100 nanometers and is made of at least one of Al, silicide, Au, Cu, Pt, ZnO, and Si. A carbon nanotube (CNT) may replace the nanowire 404. The CNT is not mechanically deformed with ease and has properties in that chemical stability and negative electron affinity are high and a field emission emitter is stable even in circumstances where an amount of vacuum is not sufficient, so that the CNT may replace the nanowire of the present invention.

The magnetic nanodot 401 may include a superparamagnetic particle made of at least any one of a metal from a group consisting of Fe, Fe₂O₃, Co, FePt, Ni, an oxide of the metals, and a ferrite, and be a size of less than approximately 20 nanometers.

The magnetic thin film 407 may include a ferromagnetic material made of at least any one of a metal from the group consisting of Fe, Fe₂O₃, Co, FePt, Ni, an oxide of the metals, and a ferrite, a multi-layer film made of the ferromagnetic material combination, and another multi-layer film made of the ferromagnetic material and an antiferromagnetic material.

FIG. 5B, parts I) through XI) illustrate a method of manufacturing a nano-magnetic memory device according to an exemplary embodiment of the present invention.

Referring to FIG 5B, an insulation substrate 402 is provided in part I), an insulation thin film 403 is stacked on the insulation substrate 402, and a metal thin film to be formed into a nanowire 404 is attached on the insulation thin film 403 in part II). The insulation thin film 403 may be made of SiO₂, Al₂O₃, Si₃N₄ and SiON and may be attached via atomic layer deposition (ALD), physical vapor deposition (PVD), chemical vapor deposition (CVD) or pulsed laser deposition (PLD). Also, it is desirable that a thickness of the insulation thin film 403 ranges from approximately 5 to 10 nanometers.

In part III), the nanowire 404 whose cross-section is a squared type, is formed via a photolithography and an etching processes. The square type may be formed due to a feature of the etching process. After this, in part IV), the nanowire 404 may be formed in a circle shape or semi-oval shape due to a surface tension via a heat treatment. The nano-magnetic memory device cell according to the present invention can be embodied even when the nanowire 404 is square shaped. Also, the nanowire 404 may include any one of a metal, a semiconductor, and an organic conductive material, which has a diameter of below approximately 100 nanometers and is made of at least one of Al, silicide, Au, Cu, Pt, ZnO, and Si. A carbon nanotube (CNT) may replace the nanowire 404. The CNT is not mechanically deformed with ease and has properties in that chemical stability and negative electron affinity are high and a field emission emitter is stable even in circumstances where an amount of vacuum is not sufficient, so that the CNT may replace the nanowire of the present invention.

In part V), another insulation thin film 408 is additionally stacked on the insulation thin film 403 formed with the nanowire 404. The other insulation thin film 408 may be made of SiO₂, Al₂O₃, Si₃N₄ and SiON, and may be attached via ALD, PVD, CVD or PLD. Also, it is desirable that a thickness of the other insulation thin film 408 ranges from approximately 5 to 100 nanometers.

In part VI), a magnetic nanodot 401, which is regularly manufactured via a colloidal method, is formed on the other insulation thin film 408. The magnetic nanodot 401 may include a superparamagnetic particle made of at least any one of a metal from a group consisting of Fe, Fe₂O₃, Co, FePt, Ni, an oxide of the metals, and a ferrite, and be a size of less than approximately 20 nanometers.

In part VII), still another insulation thin film 409 is additionally stacked on the other insulation thin film 408. The still another insulation thin film 409 may be made of SiO₂, Al₂O₃, Si₃N₄ and SiON, and may be attached via ALD, PVD, CVD or PLD.

The magnetic thin film 407 is provided on the still another insulation thin film 409 in part VIII), and a desired pattern is formed on the magnetic thin film 407 via a photolithography process in part IX).

After this, the still another insulation thin film 409 is additionally stacked on the magnetic thin film 407 in part X), the still another insulation thin film 409 is eliminated to a surface of the magnetic thin film 407 in part XI), and consequently the nano-magnetic memory device cell according to the present invention is completed.

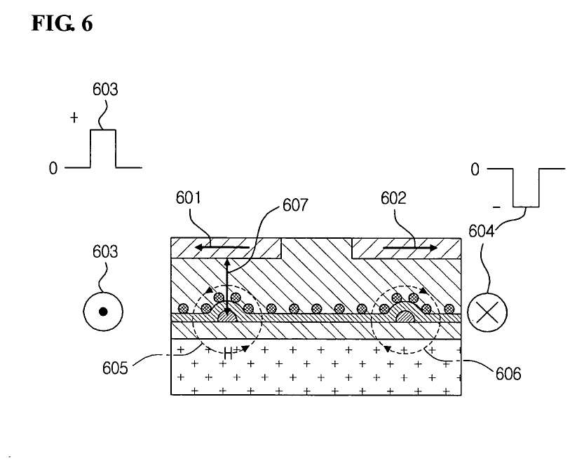

FIG. 6 is a diagram illustrating operation of a nano-magnetic memory device in a write mode according to an exemplary embodiment of the present invention.

Referring to FIG. 6, when a current pulse 603 in a positive direction is supplied to a first electrode 405, and the current pulse 603 in a positive direction begins to flow in a nanowire or a nanowire 404, a magnetic field H and a magnetic induction B induced by a current pulse I 603 flowing in the nanowire or the nanowire 404 is represented as,

$$H = \frac{I}{2 π r} , B = {μ}_{0} ( H + M ) . \qquad [ Equation 1 ]$$

In the above equation 1, r 607 indicates a distance from a center of the nanowire 404 in which the current 603 flows. M in equation 1 indicates a magnetization of the magnetic thin film 407 in FIG. 4.

Again referring to FIG. 6, when the current pulse 603 in the positive direction flows, on a basis of an outgoing direction from a surface, a magnetic field H 605 is formed in a counterclockwise direction around the nanowire 404. The magnetic thin film 407, in which a multi-layer film made of the ferromagnetic material and another multi-layer film made of the ferromagnetic material and an antiferromagnetic material, is magnetized by the magnetic field H 605 formed in the counterclockwise direction, and an induced magnetic moment 601 is induced in a direction as shown in FIG. 6. Conversely, when a current pulse signal 604 in a negative direction flows in the nanowire 404, a magnetic field H 606, on a basis of outgoing direction from a surface, is formed in a clockwise direction around the nanowire 404, and a size of the magnetic field H 606 is represented as shown in equation 1. In this case, an induced magnetic moment 602 is induced in a direction by the magnetic field H 606 formed in the clockwise direction as shown in FIG. 6. As described above, the induced magnetic moment 601 induced to the magnetic thin film 407 may record data in the nano-magnetic memory device according to a direction of the induced magnetic moment 601 because a predetermined value still remains even after the current pulse is no longer supplied to the nanowire 404, due to a ferromagnetic property of the magnetic thin film 407.

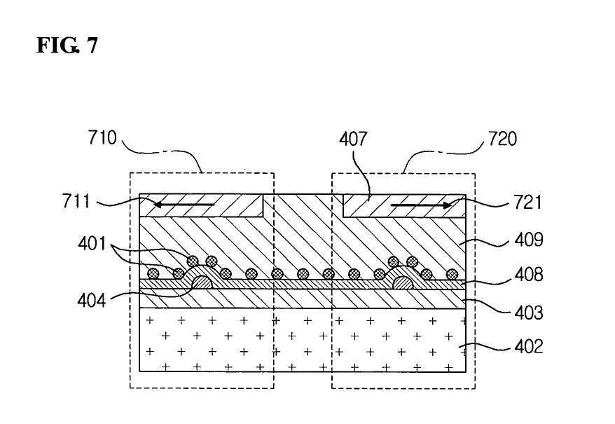

FIG. 7 is a cross-sectional view illustrating a state of the nano-magnetic memory device cell in which different data is respectively recorded on each magnetic thin film by a current flowing in the nanowire of FIG. 6.

Referring to FIG. 6, FIG. 7 will be described as follows. With respect to a nano-magnetic memory device cell 710 in the left-hand side of FIG. 7, hereinafter it will be referred to as a nano-magnetic memory device cell 710 in a state of a “1” 711. The state of a “1” 711 is recorded by a current pulse, through an electrode, supplied to a nanowire or a carbon nanotube in a positive direction. With respect to a nano-magnetic memory device cell 720 in the right-hand side of FIG. 7, hereinafter it will be called as a nano-magnetic memory device cell 720 in a state of a “0” 721. The state of a “0” 721 is recorded by a current pulse, through an electrode, supplied to a nanowire or a carbon nanotube in a negative direction. The state of a “1” 711 and state of a “0” 721 may be inversely accomplished in a virtual embodiment.

A density of the nano-magnetic memory device may be improved since only two wires are allocated to each of the nano-magnetic memory device cells 710 and 720 by supplying the current pulse for writing to flow from the first electrode 405 in FIG. 4 through the nanowire 404 to the second electrode 406 in FIG. 4. Also, a density of a nano-magnetic memory device may be improved and a cell design may be effectively planned by reducing an effective size in which a cell of the memory device occupies. Also, a manufacturing method capable of mass producing a memory device may be manufactured by solving a problem of a current magnetic field in an MRAM using a conventional metal ferromagnetic thin film, which is necessary for the magnetization reversal.

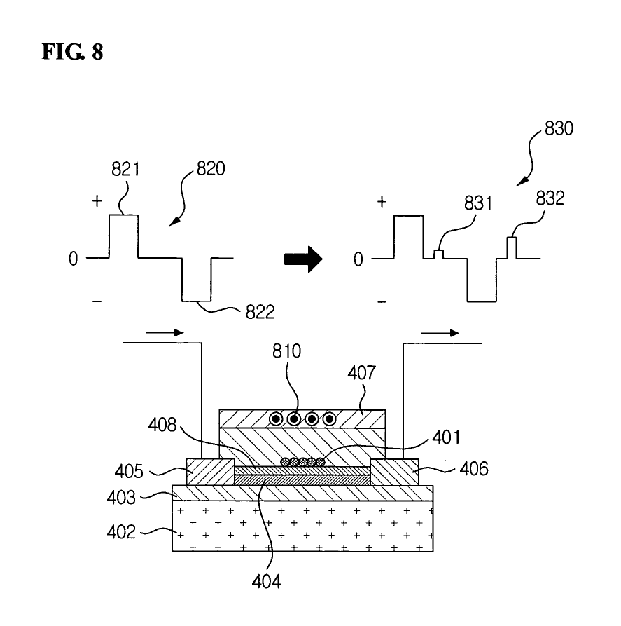

FIG. 8 is a diagram illustrating a current pulse for reading data in a state of “1” which is supplied to a nano-magnetic memory device cell, and a resultant outputted current pulse.

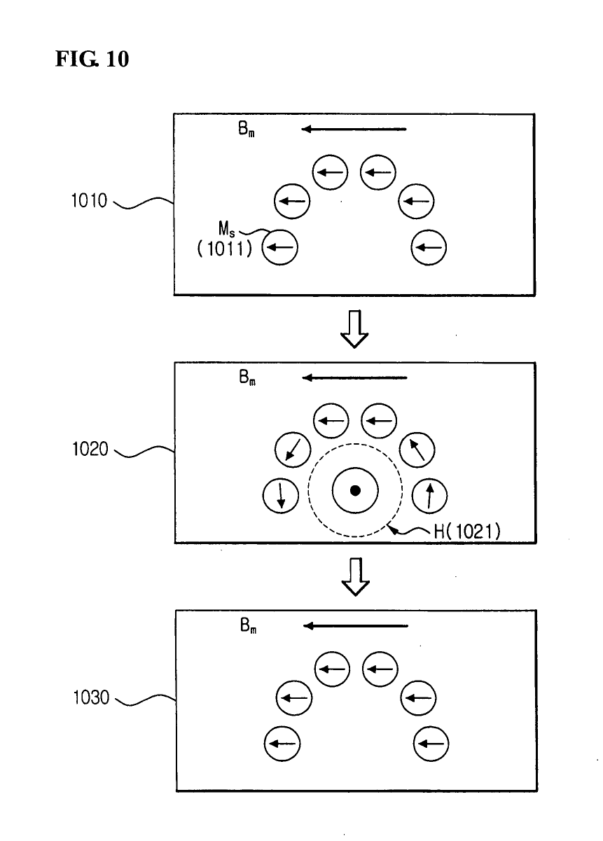

After describing operations, when a current pulse for reading in a positive direction is supplied, with reference to FIG. 10, FIG. 8 will be described in detail.

FIG. 10 is a diagram illustrating operations, when a current pulse for reading in a positive direction is supplied, after the magnetic nanodot is perturbed according to an effect of a magnetic thin film in which data is recorded and a magnetic moment is rearranged in a predetermined relaxation time.

Referring to FIG. 10, in operation 1010, a magnetic moment 1011 in a state of “1” is recorded in the magnetic thin film 407 of FIG. 4, magnetization (magnetic moments) 1011 indicates a state in which magnetization (magnetic moments) of the magnetic nanodots 401 in a superparamagnetic state are rearranged in parallel by a magnetic flux of the magnetic thin film.

In operation 1020, when a current pulse 603 in a positive direction for reading is supplied to the nanowire 404 of FIG. 4, a magnetic field H 1021 is perturbed in a counterclockwise direction according to a direction of the supplied current, and a magnetization (magnetic moments) 1011 of the nanodot 401 of FIG. 4 is rearranged in the counterclockwise direction by the magnetic field H 1021.

In operation 1030, a state of the nanodot 401 after the current pulse 603 in a positive direction for reading is supplied to the nanowire 404 is illustrated. After the current pulse 603 in a positive direction for reading is supplied to the nanowire 404, the perturbed magnetization (magnetic moment) 1011 of the magnetic nanodot 401 is rearranged in an initially arranged state of operation 1010. An induced current occurs in the nanowire 404 according to a change of a magnetization (magnetic moment) 1011 of the nanodot 401 with respect to the recovery time from the perturbed state to the initially arranged state, i.e. a relaxation time.

An occurrence of an induced current is as follows. The change of a magnetization (magnetic moment) is associated with a current occurrence, which is represented as,

$$- μ \frac{\partial M}{\partial t} = ∇ \times \frac{J}{σ} . \qquad [ Equation 2 ]$$

In the above equation 2, J indicates a current density, σ indicates a electric conductivity, and M indicates a magnetization. In the Equation 2, the induced current occurs in the nanowire 404 according to the change of the magnetic moment that is associated with a time change when the magnetization (magnetic moment) of the magnetic nanodots 401 in the superparamagnetic state are perturbed and rearranged. The minus sign in equation 2 indicates Lenz's law, i.e. the induced current is formed in a direction of resisting a change of a magnetic field.

A time change of the magnetization (magnetic moment) of the magnetic nanodot is associated with τ, i.e. the relaxation time is represented as,

$$τ = {τ}_{0} exp ( \frac{{W}_{b}}{{k}_{B} T} ) . \qquad [ Equation 3 ]$$

In equation 3, τ₀ indicates a relaxation time constant, W_{b} indicates barrier energy, ^{k}^{_{B}} indicates Boltzman constant, T indicates a temperature. Also, the barrier energy W_{b} is represented as,

W_{b}=Wₘₐₓ±Wₘᵢₙ. [Equation 4]

In equation 4, Wₘₐₓ is represented as equation 5, and Wₘᵢₙ is represented as equation 6.

$${W}_{max} = \frac{π {K}_{a} {d}_{m}^{3}}{6} [ 1 + {( \frac{{B}_{m} {M}_{s}}{2 {K}_{a}} )}^{2} ] \qquad [ Equation 5 ]$$

Wₘᵢₙ=BₘMₛVₘ [Equation 6]

In equation 5, Kₐ indicates an effective anisotropy constant. In equation 6, Vₘ indicates a magnetic volume of the magnetic nanodot 401, and in equations 5 and 6, Bₘ indicates a magnetic induction formed in the magnetic thin film 407, and Mₛ indicates a saturation magnetization of the nanodot 401.

In equations 5 and 6, when the magnetization Mₛ formed by perturbed is anti-parallel with the magnetic induction Bₘ formed on the magnetic thin film 407, the W_{b} in equation 4 is represented as,

W_{b}=Wₘₐₓ−Wₘᵢₙ. [Equation 7]

When the W_{b} is represented as equation 7, the W_{b} induces a comparatively smaller value, i.e. a faster relaxation time τ in equation 3, and the faster relaxation time may induce a greater value of a current in equation 3.

On the other hand, when the magnetization Mₛ, formed by perturbed is parallel with the magnetic induction Bₘ formed on the magnetic thin film 407, the W_{b} in equation 4 is represented as,

W_{b}=Wₘₐₓ+Wₘᵢₙ. [equation 8]

When the W_{b} is represented as equation 8, the W_{b} induces a comparatively greater value, i.e. a slower relaxation time τ in equation 3, and the slower relaxation time may induce a smaller value of a current in equation 2.

Again referring to FIG. 8, among a current pulse 820 for reading which is supplied to the nano-magnetic memory device cell to read data 810 in a state of a “1”, when the current pulse is supplied in a positive direction as described in FIG. 10, the magnetization Mₛ formed by perturbed is parallel with the magnetic induction Bₘ formed on the magnetic thin film 407. In this case, the comparatively greater value of W_{b}, and a slower relaxation time τ are induced. The slower relaxation time induces a smaller value of a current in equation 2, and the current may be induced in the positive direction according to Lenz's law. Accordingly, a current pulse 831 induced in the above described direction and size may occur in the current outputted to the second electrode.

On the other hand, among a current pulse signal 820 for reading which is supplied to the nano-magnetic memory device cell to read data 810 in a state of a “1”, when the current pulse is supplied in a negative direction, the magnetization Mₛ formed by perturbed is anti-parallel with the magnetic induction Bₘ formed on the magnetic thin film 407. In this case, the comparatively smaller value of W_{b} and a faster relaxation time are induced. The faster relaxation time induces a greater value of a current in equation 2, and the current may be induced in the positive direction according to Lenz's law. Accordingly, a current pulse 832 induced in the above described direction and size may occur in the current outputted to the second electrode.

Data recorded in the magnetic thin film may be read by analyzing a current wave form 831 induced after supplying the outputted current pulse wave form 830 in a positive direction and a current wave form 832 induced after supplying the outputted current pulse wave form 830 in a negative direction.

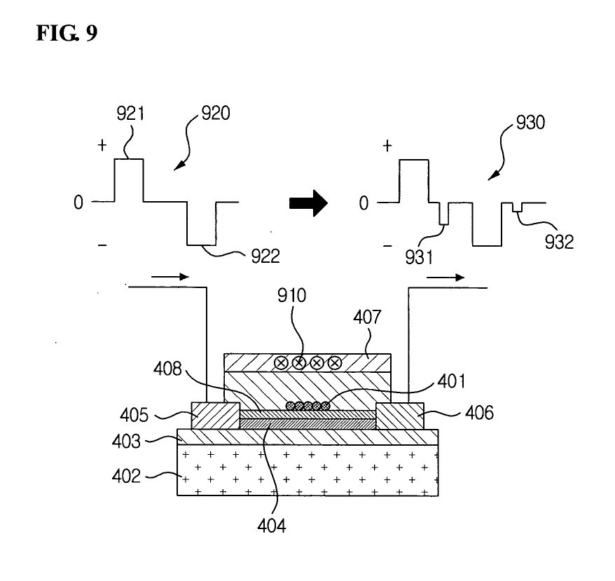

FIG. 9 is a diagram illustrating a current pulse for reading data in a state of a “0” which is supplied to a nano-magnetic memory device cell, and a resultant outputted current pulse.

Referring to FIG. 9, among a current pulse signal 920 for reading which is supplied to the nano-magnetic memory device cell to read data 910 in a state of a “0”, when the current pulse is supplied in a positive direction, as described in FIG. 10, the magnetization Mₛ formed by perturbed is anti-parallel with the magnetic induction Bₘ formed on the magnetic thin film 407. In this case, a comparatively smaller value of W_{b} and a faster relaxation time are induced, and a greater value of a current may be induced in equation 2. A direction may be induced in a negative direction according to the Lenz's law. Accordingly, a current pulse 931 induced in the above described direction and size may occur in the current outputted to the second electrode.

On the other hand, among the current pulse signal 920 for reading which is supplied to the nano-magnetic memory device cell to read data 910 in a state of a “0”, when the current pulse is supplied in a negative direction, as described in FIG. 10, the magnetization Mₛ formed by perturbed is parallel with the magnetic induction Bₘ formed on the magnetic thin film 407. In this case, a comparatively smaller value of W_{b} and a slower relaxation time are induced. A smaller value of a current may be induced in equation 2, and the current may be induced in the negative direction according to the Lenz's law. Accordingly, a current pulse 932 induced in the above described direction and size may occur in the current outputted to the second electrode.

Data recorded in the magnetic thin film may be read by analyzing the current wave form 931 induced after supplying the outputted current pulse wave form 930 in a positive direction and a current wave form 932 induced after supplying the outputted current pulse wave form 930 in a negative direction.

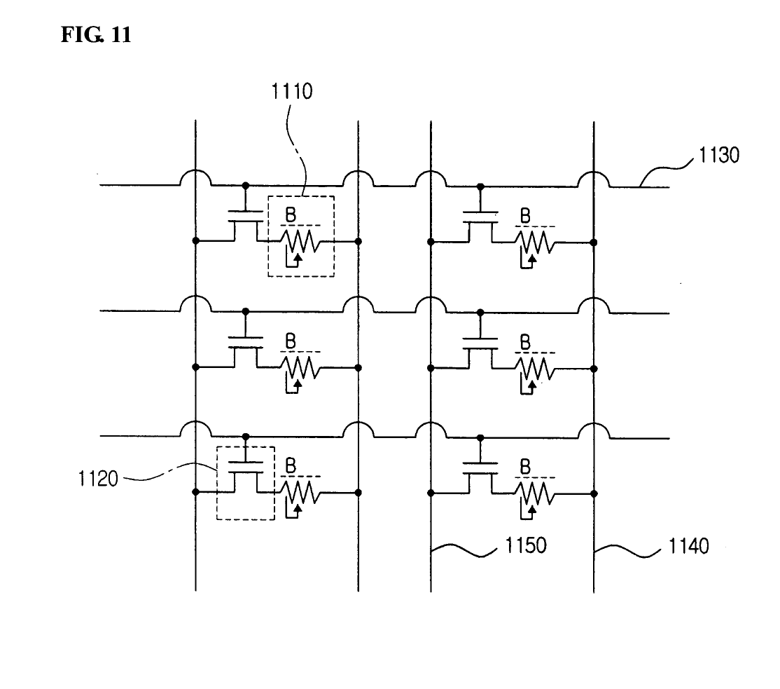

FIG. 11 is a diagram illustrating a highly integrated NOR type memory array in which a cell array of a nano-magnetic memory device is embodied according to an exemplary embodiment of the present invention.

Referring to FIG. 11, a plurality of nano-magnetic memory cell 1110 are included, wherein a first electrode of the plurality of the nano-magnetic memory cell 1110 is connected to an identical first bit line 1140, each drain of a plurality of metal-oxide-silicon (MOS) transistor 1120 is respectively connected to a second electrode 406 of the plurality of the nano-magnetic memory cell 1110, each source of the plurality of MOS transistor 1120 is respectively connected to a second bit line 1150, and each gate is respectively connected to a different word line 1130.

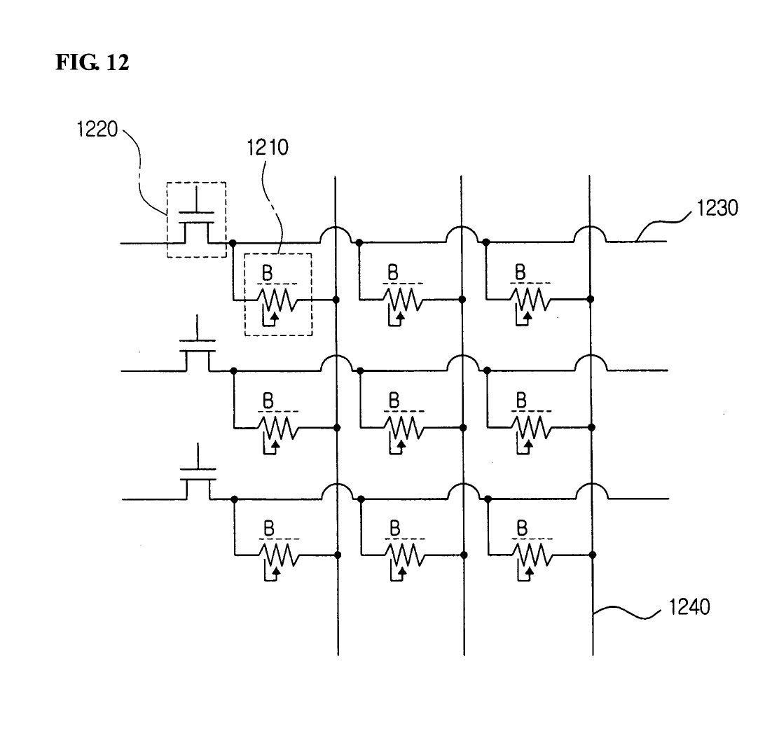

FIG. 12 is a diagram illustrating a highly integrated cross-point memory array in which a cell array of a nano-magnetic memory device is embodied according to an exemplary embodiment of the present invention.

Referring to FIG. 12, a plurality of nano-magnetic memory cell 1210 connected to an identical bit line 1240 are included, wherein a first electrode of the plurality of the nano-magnetic memory cell 1210 is connected to the identical first bit line 1240, a second electrode 406 of the plurality of the nano-magnetic memory cell 1210 is connected to a different word line 1230, and the word line 1230 is connected to a selection transistor 1220. A predetermined nano-magnetic memory cell is selected by the selection transistor 1220, as described above, data may be read and written through the word line 1230 and the bit line 1240.

According to the present invention, there is provided a nano-magnetic memory device capable of writing/reading multi data in the nano-magnetic memory cell by controlling an amount of an induced current which is formed after a magnetic nanodot is perturbed and rearranged according to a word line current flowing from the first electrode through a nanowire of the nano-magnetic memory device to the second electrode, and consequently, a size of the memory device is reduced and a density of the memory device may be improved by providing the simplified nano-magnetic memory device of which a cell size is smaller.

Also, according to the present invention, there is provided a nano-magnetic memory device capable of improving a density of a memory device and planning an effective cell design by reducing an effective area in which a cell of the memory device occupies.

Also, according to the present invention, there is provided a nano-magnetic memory manufacturing method capable mass producing a memory device by solving a problem of a current magnetic field necessary for a magnetization reversal, contrary to an MRAM using a conventional metal ferromagnetic thin film.

Also, according to the present invention, there is provided a nano-magnetic memory device capable of making a manufacturing process simple by simplifying a cell structure of a conventional memory device.

Also, according to the present invention, there is provided a nano-magnetic memory device capable of improving a density of a memory device by decreasing a number of metal wires for each cell.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A nano-magnetic memory device comprising:
a nano-magnetic memory cell comprising:
a first dielectric layer stacked on an insulation substrate;
a first electrode and a second electrode formed in both sides of the first dielectric layer;
a nanowire connecting the first electrode and the second electrode, and stacked on a top surface of the first dielectric layer;
at least one magnetic nanodot formed on a top surface of the nanowire;
a second dielectric layer stacked on a top surface of the magnetic nanodot; and
a magnetic thin film layer stacked on a top surface of the second dielectric layer,
wherein the nano-magnetic memory device is configured to write/read a plurality of data in the nano-magnetic memory cell by controlling an amount of an induced current which is formed after the magnetic nanodot is perturbed and rearranged according to a word line current flowing from the first electrode through the nanowire to the second electrode.

2. The device of claim 1, wherein the nanowire includes any one of a metal, a semiconductor and an organic conductive material, which is made of at least one of Al, silicide, Au, Cu, Pt, ZnO, and Si.

3. The device of claim 1, wherein the nanowire has a diameter less than approximately 100 nanometers.

4. The device of claim 1, wherein the magnetic nanodot includes a superparamagnetic particle made of at least any one of a metal from a group comprising of Fe, Fe₂O₃, Co, FePt, Ni, an oxide of the metals, and a ferrite.

5. The device of claim 1, wherein the magnetic nanodot has a size less than approximately 20 nanometers.

6. The device of claim 1, wherein the magnetic thin film layer comprises at least any one of (1) a ferromagnetic material (metal, an oxide of the metal, and ferrite), (2) a multi-layer made of the ferromagnetic material and (3) another multi-layer made of the ferromagnetic material and an antiferromagnetic material.

7. A nano-magnetic memory device comprising:
one or more nano-magnetic memory cells connected to an identical first bit line by first electrodes of one or more nano-magnetic memory cells,
wherein each individual drain of one or more metal-Oxide-Silicon (MOS) transistors is respectively connected to second electrodes of the one or more nano-magnetic memory cells, each individual source of one or more MOS transistors is respectively connected to a second bit line, and each individual gate of the one or more MOS transistors is respectively connected to a different word line.

8. A nano-magnetic memory device comprising:
a plurality of nano-magnetic memory cells connected to an identical bit line,
wherein a first electrode of the plurality of nano-magnetic memory cells is connected to the bit line, a second electrode of the plurality of nano-magnetic memory cells is connected to a different word line, and the word line is connected to a selection transistor, and
the plurality of nano-magnetic memory cells includes
a first dielectric layer stacked on an insulation substrate,
a first electrode and a second electrode formed in both sides/ends of the first dielectric layer,
a nanowire connecting the first electrode and the second electrode, and stacked on a top surface of the first dielectric layer,
at least one magnetic nanodot formed on a top surface of the nanowire,
a second dielectric layer stacked on a top surface of the magnetic nanodot, and
a magnetic thin film layer stacked on a top surface of the second dielectric layer.

9. The device of claim 7, wherein the one or more nano-magnetic memory cells comprises:
a first dielectric layer stacked on an insulation substrate;
a first electrode and a second electrode formed in both sides/ends of the first dielectric layer;
a nanowire connecting the first electrode and the second electrode, and stacked on a top surface of the first dielectric layer;
at least one magnetic nanodot formed on a top surface of the nanowire;
a second dielectric layer stacked on a top surface of the magnetic nanodot; and
a magnetic thin film layer stacked on a top surface of the second dielectric layer.

10. The device of claim 8, wherein the nanowire includes any one of a metal, a semiconductor, and an organic induced material, which is made of at least one of Al, silicide, Au, Cu, Pt, ZnO or Si.

11. The device of claim 8, wherein the nanowire has a diameter less than approximately 100 nanometers.

12. The device of claim 8, wherein the magnetic nanodot includes a superparamagnetic particle made of at least any one of a metal from a group consisting of Fe, Fe₂O₃, Co, FePt, Ni, an oxide of the metals, and a ferrite.

13. The device of claim 8, wherein the magnetic nanodot has a size less than approximately 20 nanometers.

14. The device of claim 8, wherein the magnetic thin film layer comprises at least any one of (1) a ferromagnetic material (metal, an oxide of the metal, and ferrite), (2) a multi-layer made of the ferromagnetic material and (3) another multi-layer made of the ferromagnetic material and an antiferromagnetic material.

15. A method of manufacturing a nano-magnetic memory device comprising:
stacking a first dielectric layer on an insulation substrate;
forming a first electrode and a second electrode in both sides of the first dielectric layer;
stacking a nanowire on a top surface of the first dielectric layer connecting the first electrode and the second electrode;
forming at least one magnetic nanodot on a top surface of the nanowire;
stacking a a second dielectric layer on a top surface of the magnetic nanodot; and
stacking a magnetic thin film layer on a top surface of the second dielectric layer,
wherein the nano-magnetic memory device writes/reads a plurality of data in the nano-magnetic memory cell by controlling an amount of an induced current which is formed after the at least one magnetic nanodot is perturbed and rearranged according to a word line current flowing from the first electrode through the nanowire to the second electrode.

16. The method of claim 15, wherein the nanowire includes any one of a metal, a semiconductor and an organic induced material, which is made of at least one of Al, silicide, Au, Cu, Pt, ZnO or Si.

17. The method of claim 15, wherein the nanowire has a diameter less than approximately 100 nanometers.

18. The method of claim 15, wherein the magnetic nanodot includes a superparamagnetic particle made of at least any one of a metal from a group consisting of Fe, Fe₂O₃, Co, FePt, Ni, an oxide of the metals, and a ferrite.

19. The method of claim 15, wherein the magnetic nanodot has a size less than approximately 20 nanometers.

20. The method of claim 15, wherein the magnetic thin film layer comprises at least any one of (1) a ferromagnetic material (metal, an oxide of the metal, and ferrite), (2) a multi-layer made of the ferromagnetic material and (3) another multi-layer made of the ferromagnetic material and an antiferromagnetic material.
